(19) United States
(12) Patent Application Publication
(10) Pub. No.: US 2025/0058675 A1
(43) Pub. Date: Feb. 20, 2025

(54) BATTERY UNIT AND BATTERY MONITORING APPARATUS

(71) Applicant: DENSO CORPORATION, Kariya-city (JP)

(72) Inventors: Tatsuhiro NUMATA, Kariya-city (JP); Masaki UCHIYAMA, Kariya-city (JP); Taisuke KURACHI, Kariya-city (JP); Tetsuya WATANABE, Kariya-city (JP)

(73) Assignee: DENSO CORPORATION, Kariya-city (JP)

(21) Appl. No.: 18/938,850

(22) Filed: Nov. 6, 2024

Related U.S. Application Data
(63) Continuation of application No. PCT/JP2023/017133, filed on May 2, 2023.

(30) Foreign Application Priority Data
Jun. 1, 2022 (JP) 2022-089528

(51) Int. Cl. B60L 58/18; B60L 50/64; B60L 53/80; B60L 58/12

(52) U.S. Cl. CPC B60L 58/18; B60L 50/64; B60L 53/80; B60L 58/12; B60L 2240/547; B60L 2240/549

(57) ABSTRACT

A battery unit configured to be exchangeable with respect to an external load, in which the battery unit includes: a battery member capable of supplying power to the external load in a state where the battery unit is connected to the external load; a battery load connected to the battery member, a measurement unit that measures at least either a current flowing through the battery load or a voltage applied to the battery load; and a control unit configured to operate with the battery member as a power source in a state where the battery unit is removed from the external load, cause a current to flow to the battery load from the battery member at a predetermined timing and acquire a measurement result measured by the measurement unit at a time when the current is caused to flow.

This application is the U.S. bypass application of International Application No. PCT/JP2023/017133 filed on May 2, 2023 which designated the U.S. and claims priority to Japanese Patent Application No. 2022-089528 filed on Jun. 1, 2022, the contents of both of these are incorporated herein by reference.

### BACKGROUND

### Technical Field

The present disclosure relates to a battery unit and a battery monitoring apparatus.

### Description of the Related Art

A configuration is known in which a degree of deterioration of each of battery cells constituting a battery module is detected after removing the battery module from the battery pack. For example, a configuration is disclosed in which a degree of deterioration is calculated before removing a battery module from a battery pack and the calculated deterioration degree is transmitted to an external apparatus. Then, the external apparatus is referred to after removing the battery module from the battery pack. Thus, the degree of deterioration can be detected.

### SUMMARY

The present disclosure provides a battery unit configured to be exchangeable with respect to an external load, including a battery member capable of supplying power to the external load in a state where the battery unit is connected to the external load; a battery load connected to the battery member, a measurement unit that measures at least either a current flowing through the battery load or a voltage applied to the battery load; and a control unit configured to operate with the battery member as a power source in a state where the battery unit is removed from the external load, cause a current to flow to the battery load from the battery member at a predetermined timing and acquire a measurement result measured by the measurement unit at a time when the current is caused to flow.

### BRIEF DESCRIPTION OF THE DRAWINGS

The above-described objects and other objects, features and advantages of the present disclosure will be clarified further by the following detailed description with reference to the accompanying drawings. The drawings are:

FIG. 1 is a diagram showing a vehicle;

FIG. 2 is a diagram showing a perspective view of an inside portion of a battery pack;

FIG. 3 is a block diagram showing a battery control unit and a battery monitoring apparatus;

FIG. 4 is a block diagram showing a state where the battery pack is removed;

FIG. 5 is a block diagram showing a state where a battery module is removed;

FIG. 6 is a block diagram showing a determination whether the battery pack is removed;

FIG. 7 is a block diagram in the case where the battery monitoring apparatus performs some of the functions of the battery control unit;

FIG. 8 is a block diagram in the case where the battery monitoring apparatus performs some of the functions of the battery control unit;

FIG. 9 is a flowchart explaining one operation example of a battery control unit according to a first embodiment;

FIG. 10 is a flowchart explaining one operation example of a battery control unit according to a second embodiment;

FIG. 11 is a block diagram explaining another embodiment; and

FIG. 12 is a block diagram explaining yet another embodiment.

### DETAILED DESCRIPTION OF THE PREFERRED EMBODIMENTS

A configuration is known in which a degree of deterioration of each of battery cells constituting a battery module is detected after removing the battery module from the battery pack. For example, JP-A-2021-163650 discloses a configuration in which a degree of deterioration is calculated before removing a battery module from a battery pack and the calculated deterioration degree is transmitted to an external apparatus. Then, the external apparatus is referred to after removing the battery module from the battery pack. Thus, the degree of deterioration can be detected.

A storage environment of the battery module is not certain after removing the battery module from the battery pack. Depending on the storage environment, a degree of deterioration of the battery cells constituting the battery module may increase. Hence, a degree of deterioration of the battery cells after removing the battery module is required to be detected. However, according to the configuration disclosed by JP-A-2021-163650, since charging/discharging cannot be performed after removing the battery module, only the degree of deterioration before removing the battery module is detected and the degree of deterioration after removing the battery module cannot be detected.

Hereinafter, with reference to the drawings, embodiments of the present disclosure will be described. In the drawings, for the same configurations, the same reference symbols are applied and the explanation thereof will be omitted.

### First Embodiment

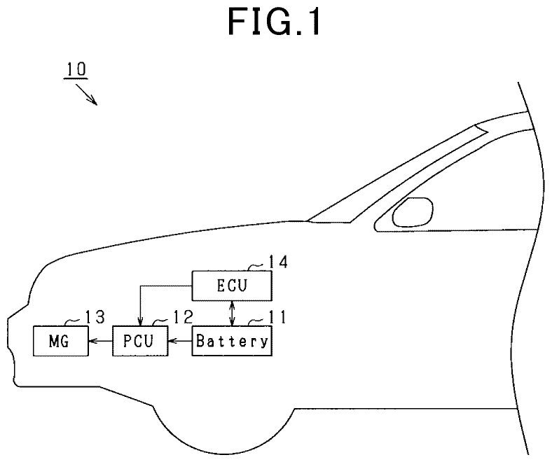

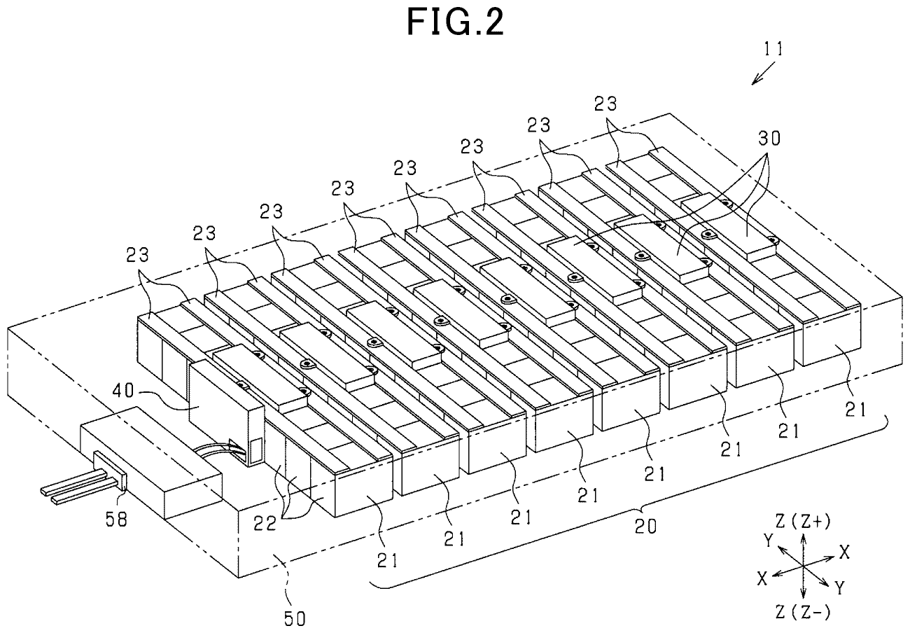

With reference to FIGS. 1 and 2, a configuration example of a battery pack 11 mounted on a vehicle 10 will be described.

### <Overall Configuration of Vehicle 10>

FIG. 1 is a diagram schematically showing a configuration of the vehicle 10. The vehicle 10 is provided with a battery pack 11 (indicated as Battery in FIG. 1), a power control unit (hereinafter referred to as PCU (Power Control Unit)) 12, a motor 13 (indicated as MG in FIG. 1), and a vehicle ECU 14 (indicated as ECU in FIG. 1). Note that embodiments in which the battery pack 11 is applied to the vehicle 10 will be described, but the battery pack 11 according to the present embodiment may be applied to configurations other than the vehicle.

The battery pack 11 is mounted to the vehicle 10 as a driving source of the vehicle 10. In FIG. 1, the battery pack 11 is installed in an engine compartment of the vehicle 10, but it is not limited thereto. The battery pack 11 may be installed in a trunk, under a seat or under the floor of the vehicle. The vehicle 10 is an electric vehicle or a hybrid-vehicle which travels using electric power stored in the battery pack 11.

The battery pack 11 includes a battery assembly 30 configured of a plurality of battery cells 22 (secondary battery cell). In more detail, a plurality of battery cells 22 connected in series and/or connected in parallel constitute a battery module 21 (also referred to as a battery stack or a battery block), and a plurality of battery modules 21 are connected in series to constitute the battery assembly 20. The battery cells 22 are each configured of a lithium-ion secondary battery, a nickel-hydrogen battery or the like. Note that the lithium-ion secondary battery refers to a secondary battery in which lithium is a charge-carrier, and the lithium-ion secondary battery may include so-called solid-state battery using a solid electrolyte other than a general lithium-ion secondary battery of which the electrolyte is a liquid.

The battery pack 11 stores electric power for driving the motor 13 at the battery assembly 20 and is capable of supplying the power to the motor 13 via the PCU 12. Also, the battery pack 11 accepts a generated power of the motor 13 via the PCU 12 when the motor 13 is in a regenerative operation such as a vehicle braking, whereby the battery pack 11 is charged.

The battery pack 11 is provided with a monitoring unit that monitors the battery assembly 20 and a control unit that executes predetermined processes in response to a monitoring result of the monitoring unit. The configurations of the monitoring unit and the control unit will be described later in detail with reference to FIG. 2 and latter drawings.

The PCU 12 executes a bi-directional power conversion between the battery pack 11 and the motor 13 in accordance with a control signal transmitted from the vehicle ECU 14. For example, the PCU 12 may be configured of an inverter that drives the motor 13 and a converter that boosts a DC voltage supplied to the inverter to be higher than or equal to an output voltage of the battery pack 11.

The motor 13 is an AC rotary electric machine, for example, a three-phase synchronous motor in which permanent magnets are embedded to the rotor. The motor 13 generates a rotational driving force when being driven by the PCU 12, and the driving force generated by the motor 13 is transmitted to the driving wheels. On the other hand, when the vehicle 10 is braking, the motor 13 operates as a generator and performs a regenerative generation. The power generated by the motor 13 is supplied to the battery pack 11 via the PCU 12 and stored in the battery assembly 20 in the battery pack 11.

The vehicle ECU 14 is configured to include CPU, ROM and RAM, and input-output ports for receiving or transmitting various signals. The CPU loads programs stored in the ROM into the RAM, and executes them. The programs stored in the ROM includes programs corresponding to processes of the vehicle ECU 14. As an example of a major process of the vehicle ECU 14, the vehicle ECU 14 receives, from the battery pack 11, information such as voltage, current, SOC (i.e. state of charge) of the battery assembly 20 and controls the PCU 12, thereby driving the motor 13 and controlling a charging or discharging operation of the battery pack 11.

### <Configuration of Battery Pack 11>

FIG. 2 is a perspective view schematically showing an inside part of the battery pack 11. The battery pack 11 is provided with a battery assembly 20, a plurality of battery monitoring units 30, a battery control unit 40 and a housing 50 that accommodates them. A connector 58 is provided at a side surface of the housing 50 for connecting the battery pack 11 with an external apparatus. Hereinafter, at an installation surface which is installed to the vehicle 10 (lower surface in FIG. 2) among respective surfaces of the housing 50 as a rectangular parallelepiped, a longitudinal direction is defined as X-direction and a short-side direction is defined as Y-direction. Then, a vertical direction orthogonal to the installation surface is defined as Z-direction. According to the present embodiment, the horizontal direction of the vehicle 10 corresponds to the X-direction and the longitudinal direction (front-rear direction) corresponds to the Y-direction and the vertical direction corresponds to the Z-direction. However, the battery pack 11 may be disposed arbitrarily with respect to the vehicle 10.

### <Configuration of Battery Assembly 20>

The battery assembly 20 includes a plurality of battery modules 21 arranged in the X direction. The plurality of battery modules 21 are connected in series, thereby constituting the battery assembly 20. The respective battery modules 21 each include a plurality of battery cells 22 arranged in the Y direction. The plurality of battery cells 22 are connected in series, thereby constituting the battery module 21.

A bus-bar unit 23 having linear shape is disposed at both ends in the X direction on the upper surface of each battery module 21. The bus-bar unit 23 electrically connects the battery cells 22.

### <Configuration of Battery Monitoring Unit 30>

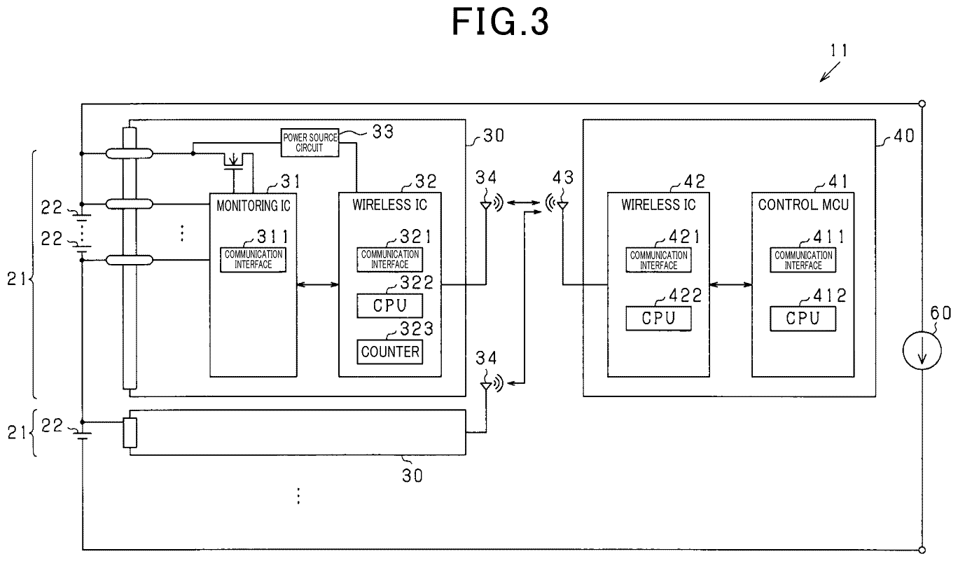

The battery monitoring unit 30 is also referred to as a satellite battery module (SGM) and provided at each battery module 21. As shown in FIG. 2, the satellite battery module is disposed between the bus-bar units 23 disposed at both ends of each battery module 21. As shown in FIG. 3, each battery monitoring unit 30 is provided with a monitoring IC 31 as a monitoring part, a wireless IC 32 as a monitoring side wireless part, a wireless antenna 34 and the like. The monitoring IC 31 is also referred to as a cell supervising circuit (CSC), acquiring battery information from respective battery cells 22 that constitute the battery module 21. The battery information includes, for example, voltage information, temperature information, current information, self-diagnosis information and the like of the respective battery cells 22. The self-diagnosis information is, for example, information related to a functionality test of the battery monitoring unit 30, that is, information related to an abnormality or a malfunction of the battery monitoring unit 30. Specifically, the self-diagnosis information is information related to a functionality test of the monitoring IC 31 or the wireless IC 32 that constitute the battery monitoring unit 30.

The wireless IC 32 is connected to the monitoring IC 31 by wiring and serves as a microprocessor having a communication interface 321, a CPU 322 and a counter 323. In FIG. 3, due to a space restriction, ROM or RAM are omitted, but the wireless IC 32 also includes ROM and RAM. The same applies to configurations shown in FIG. 3 and latter. The monitoring IC 31 includes a communication interface 311. The wireless IC 32 and the monitoring IC 31 exchange data via the communication interface. The wireless IC 32 transmits data received from the monitoring IC 31 to the battery control unit 40. Further, the wireless IC 32 transmits the data received via the wireless antenna 34 to the monitoring IC 31. The counter 323 is a logic circuit that counts the number of ON-OFF signals inputted from an input device such as a switch or a sensor and measures time.

The wireless IC 32 is connected to a battery cell 22 via a power source circuit 33. The wireless IC 32 operates by a power supplied from the battery cell 22 via the power source circuit 33.

### <Configuration of Battery Control Unit 40>

The battery control unit 40 is also referred to as a battery ECU or a BMU (battery management unit) and attached to an outer side surface of the battery module 21 which is disposed at one end in the X direction. The battery control unit 40 is configured to be capable of communicating with respective battery monitoring units 30.

When describing in more detail, as shown in FIG. 3, the battery control unit 40 is provided with a control MCU 41 as a control unit, a wireless IC 42 as a control side wireless unit, a wireless antenna 43 and the like. The control MCU 41 is a microprocessor having a communication interface 411 and a CPU 412. Also, for the control MCU 41, similar to the wireless IC 32, illustration of ROM, RAM and the like is omitted, but the control MCU 41 also includes ROM and RAM. The CPU 412 loads programs stored in the ROM into the RAM, and executes them. The programs stored in the ROM includes programs corresponding to processes for battery control.

As an example of a major process of the control MCU 41, the control MCU 41 commands the battery monitoring unit 30 to acquire the battery information and transmit the battery information. Further, the control MCU 41 monitors, based on the battery information received from the battery monitoring unit 30, the battery assembly 20, the battery module 21 and the battery cell 22. The control MCU 41 controls a relay switch that changes a conduction state between the battery assembly 20 and the PCU 12 or the motor 13 to be conduction or non-conduction. Further, the control MCU 41 transmits a voltage equalization command signal. The voltage equalization command signal will be described later in more detail. According to the present embodiment, the vehicle ECU 14 transmits a command to the PCU 12 for performing the charge-discharge control of the battery assembly 20. However, the control MCU 41 may be configured to command the PCU 12.

The wireless IC 42 is connected to the control MCU 41 by wiring and configured, similar to the wireless IC 32, as a microprocessor having a communication interface 421 and a CPU 422. Also for the wireless IC 42, similar to the wireless IC 32, illustration of ROM and RAM is omitted, but the wireless IC 42 includes ROM and RAM. The wireless IC 42 transmits the data received from the control MCU 41 to the battery monitoring unit 30 via the wireless antenna 43. The wireless IC 42 transmits data received via the wireless antenna 43 to the control MCU 41.

According to the present embodiment, the battery control unit 40 exchanges data with the battery monitoring unit 30 with a wireless communication. However, it is not limited thereto. The battery control unit 40 and the battery monitoring unit may be connected by wiring. Note that a reference symbol 60 shown in FIG. 3 indicates a load to which electric power is supplied from the battery pack 11, such as the motor 13 for example.

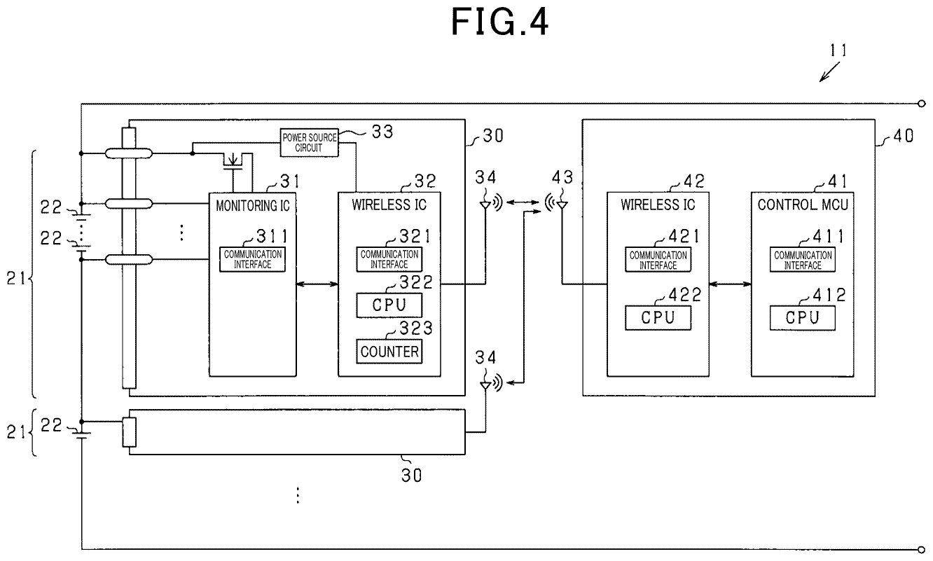

Next, a case will be considered in which the battery pack 11 described with reference to FIGS. 2 to 3 is removed from the vehicle 10. An example of a purpose for removing the battery pack 11 from the vehicle 10 is so-called 3R (i.e. reduction, reuse and recycle). FIG. 4 shows a state where the battery pack 11 is removed from the vehicle 10. According to the present embodiment, ‘state where the battery pack 11 is removed from the vehicle 10’ refers to a state where the battery pack itself is removed from the vehicle 10 but the battery modules 21 that constitute the battery pack 11 are not disassembled. In other word, ‘state where the battery pack 11 is removed from the vehicle 10’ refers to a state where although the battery pack 11 is separated from the load 60, the configuration of the battery pack 11 is not changed.

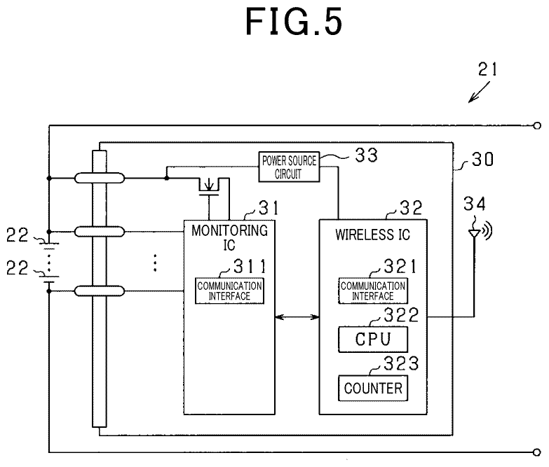

When recycling the battery pack 11, the battery pack 11 itself may be recycled or the battery modules 21 that constitute the battery pack 11 may be recycled. In the case where the battery modules 21 that constitute the battery pack 11 are recycled, the battery modules 21 are required to be removed from the battery pack 11. FIG. 5 shows a state where one battery module among a plurality of battery modules is removed from the battery pack 11. Hereinafter, this state is referred to as ‘state where battery module 21 is removed from battery pack 11’. When the battery module 21 is removed from the battery pack 11, the battery pack 11 may be removed from the vehicle 10 or may be kept mounted on the vehicle 10. Note that a state where only one remaining battery module 21 is removed from the battery pack 11 as the last battery module 21 also corresponds to a state where all battery modules 21 are removed from battery pack 11.

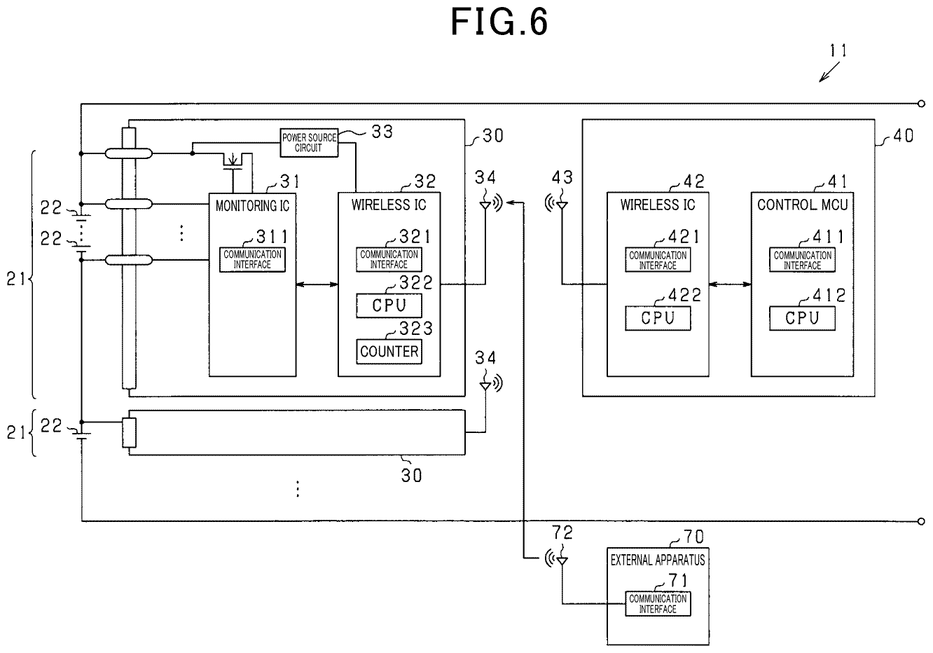

Next, with reference to FIG. 6, an example of a method for determining whether the battery pack 11 is removed from the vehicle 10 will be described. As described above, the battery monitoring unit 30 (wireless IC 32) and the battery control unit 40 constantly exchange data. The wireless IC 32 determines that communication with the battery control unit 40 is cutoff when an activation command signal or a voltage equalization command signal for the battery cells 22 from the battery control unit 40 have not been received for a prescribed period (T1). Note that ‘activation command signal’ refers to a signal inputted when the ignition switch of the vehicle 10 is turned ON, and ‘voltage equalization command signal’ refers to a signal inputted when equalizing the voltages of the battery cells 22. The voltage equalization command signal is transmitted at a prescribed period (T2) to the wireless IC 32 from the battery control unit 40 (T1>T2) even when the ignition switch is OFF. Hence, as long as the battery pack 11 is mounted on the vehicle 10, the wireless IC 32 receives the voltage equalization signal at each prescribed period (T2). On the other hand, when the battery pack 11 is removed from the vehicle 10, neither activation command signal nor voltage equalization signal are transmitted to the wireless IC 32 from the battery control unit 40.

In other words, a case where these signals have not been inputted for a prescribed period (T1) refers to a case where the battery pack 11 is not mounted to the vehicle 10 or unlikely to be mounted to the vehicle 10. Hence, in the case where a predetermined signal has not been received for a prescribed period, the wireless IC 32 determines that a communication with the battery control unit 40 is cutoff. Then, when determined that the communication with the battery control unit 40 is cutoff, the wireless IC 32 determines that the battery pack 11 is removed from the vehicle 10. Such a function of the wireless IC 32 (function of the CPU 322 of the wireless IC 32) corresponds to determination unit.

As another determination method, as shown FIG. 6, a signal transmitted from an external apparatus 70 may be utilized. An example of the external apparatus 70 is an inspection equipment used when a vehicle is inspected. In the case where the wireless IC 32 receives a signal indicating that the communication is cutoff transmitted from the external apparatus 70 via a wireless antenna 72, the wireless IC 32 may determine that the communication with the battery control unit 40 is cutoff.

In FIG. 6, a method for determining whether the battery pack 11 is removed from the vehicle 10 is described. However, the same method can be applied to a determination whether the battery module 21 is removed from the battery pack 11.

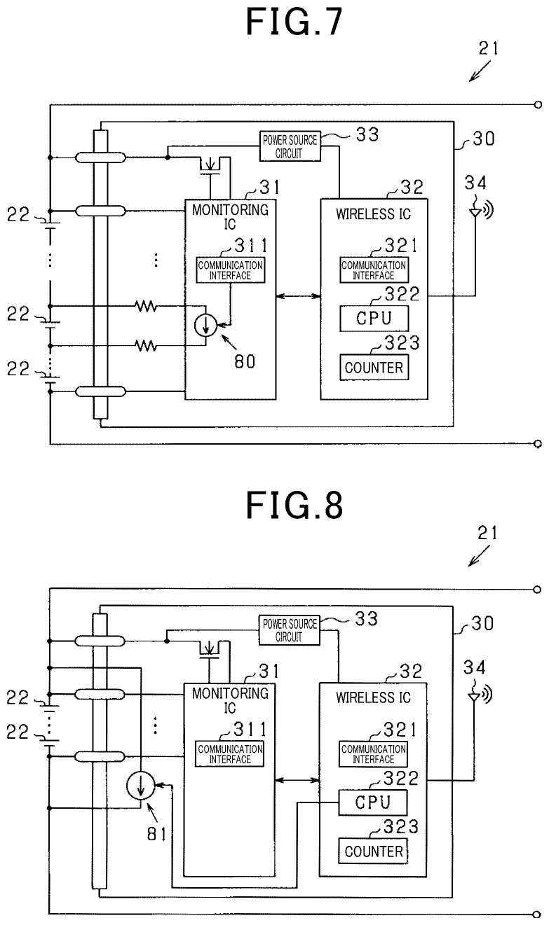

Next, referring to FIG. 7, a process performed after determining that the battery module 21 is removed from the battery pack 11 will be described. In FIG. 7, it is assumed that the battery pack 11 is mounted to the vehicle 10 before removing the battery module 21 is removed from the battery pack 11. When determined that the battery module 21 is removed from the battery pack 11, the battery monitoring unit 30 (wireless IC 32) performs functions which have not been performed in a state where the battery module 21 is mounted to the battery pack 11. Note that ‘functions not performed in a state where the battery module 21 is mounted to the battery pack 11’ refers to functions performed by the battery control unit 40 in a state where the battery module 21 is mounted to the battery pack 11. Specifically, when determined that the battery module 21 is removed from the battery pack 11, the wireless IC 32 performs, instead of the battery control unit 40, functions performed by the battery control unit 40 in a state where the battery module 21 is mounted to the battery pack 11. Note that the functions performed by the wireless IC 32 instead of the battery control unit 40 may be all of the functions performed by the battery control unit 40 or a part of the functions performed by the battery control unit 40. Here, it will be described assuming that the functions performed by the wireless IC 32 instead of the battery control unit 40 are a part of the functions performed by the battery control unit 40. Note the purpose for performing the functions by the wireless IC instead of the battery control unit 40 is different from the original purpose. This will be described later.

A function performed by the battery control unit 40 in a state where the battery module 21 is mounted to the battery pack 11 is, for example, a transmission of the above-described voltage equalization command signal. The voltage equalization command signal refers to a signal transmitted by the battery control unit 40 to the battery monitoring unit 30 (wireless IC 32) for equalizing voltages of the respective battery cells 22. This signal is further transmitted to the monitoring IC 31 from the wireless IC 32. The monitoring IC 31 drives the voltage equalization circuit 80, thereby equalizing the voltages of the respective battery cells 22. The voltage equalization circuit 80 refers to a circuit that outputs a predetermined current using the battery cell 22 as a power source.

After determining that the battery module 21 is removed from the battery pack 11, the wireless IC 32 performs a transmission of the voltage equalization command signal which was performed by the battery control unit 40 before removing the battery module 21. Specifically, the wireless IC 32 transmits the voltage equalization command signal to the monitoring IC 31. Here, the purpose of transmitting the voltage equalization command signal by the battery control unit 40 is to equalize the voltages of the respective battery cells 22. As described above, the purpose of transmitting the voltage equalization signal by the wireless IC 32 is different from the original purpose. That is, the purpose of transmitting the voltage equalization command signal by the wireless IC 32 is not for equalizing the voltages of the respective battery cells 22. The purpose of transmitting the voltage equalization command signal by the wireless IC 32 is for measuring parameters used for calculating the SOH of each battery cell 22. Hence, the wireless IC 32 transmits the voltage equalization command signal to the monitoring IC 31 such that all of the voltage equalization circuits 80 connected to respective battery cells 22 are driven.

The monitoring IC 31 shown in FIG. 7 drives the voltage equalization circuit 80 in accordance with the command of the monitoring IC 31. The monitoring IC 31 measures at least either the current flowing through the voltage equalization circuit 80 or the voltage applied to the voltage equalization circuit 80. Of course, the monitoring IC 31 may measure both of the current and voltage, and may measure the temperature at the time of measuring the current or the voltage. For measuring the temperature, a cell thermistor may be used for example.

The monitoring IC 31 transmits measured current and the like to the wireless IC 32. The wireless IC 32 calculates a battery state of the battery cell 22 using the current acquired from the monitoring IC 31. According to the present embodiment, ‘battery state of battery cell 22’ refers to SOH (state of health) of the battery cell 22. Also, the SOH is referred to a degradation state in addition to a state of health. An example of a calculation method of the SOH will be described. Generally, for the SOH, two indexes of a capacity retention rate and an increase rate of an internal resistance are known. The capacity retention rate is a ratio of full-capacity of new battery to current full-capacity of the battery. The increase rate of the internal resistance is an increase rate of the internal resistance which increases accompanying with a degradation of the battery. Note that the physical quantity capable of being externally measured is current, voltage and temperature, and it is difficult to directly measure the SOH. In this respect, an OCV (open circuit voltage) estimation method, a non-linear Kalman filter and the like are known. The wireless IC 32 calculates the SOH using these methods. Other than the above-described two indexes, a method of calculating the SOH using SOC or the internal resistance of the battery is also known. Hence, the wireless IC 32 may calculate the SOH using these methods. In the case where the battery module 21 is removed from the battery pack 11, the wireless IC 32 operates with the battery cell 22 as the power source.

Thus, according to the present embodiment, after determining that the battery module 21 is removed from the battery pack 11, the wireless IC 32 discharges the battery cell 22 at a predetermined timing, thereby calculating the SOH. As described above, according to the conventional art, since charging/discharging cannot be performed after removing the battery module, the SOH after removing the battery module cannot be detected. In contrast, according to the present embodiment, since the battery cells 22 are caused to be discharged to calculate the SOH, the SOH after removing the battery module can be detected.

Also, according to the present embodiment, after it is determined that the battery module 21 is removed from the battery pack 11, the wireless IC 32 performs a transmission process of the voltage equalization command signal which is performed by the battery control unit 40 before removing the battery module 21. The purpose of transmitting the voltage equalization command signal by the battery control unit 40 is to equalize the respective battery cells 22. However, the purpose of transmitting the voltage equalization command signal by the wireless IC 32 is to measure parameters used for calculating the SOH, which is different from the purpose of transmitting the voltage equalization command signal by the battery control unit 40. That is, according to the present embodiment, the wireless IC 32 utilizes a function performed by the battery control unit 40 of which the purpose is different from the original purpose. Such an existing function is utilized for a different purpose, whereby it is not necessary to add new functions and apparatuses. Hence, cost reduction can be accomplished.

In FIG. 7, a case of transmitting the voltage equalization command signal is exemplified as a function performed by the battery control apparatus 40 before removing the battery module 21 from the battery pack 11. However, it is not limited thereto. That is, as long as the current can be drawn from the battery cell 22, for example, as shown in FIG. 8, the wireless IC instead of the battery control apparatus may perform the function of transmitting the drive signal to a module equalization circuit 81. Further, the battery control unit 40 has a function of driving a circuit for adjusting a temperature state of the battery cell 22 and a function of driving a circuit for measuring the impedance of the battery cell 22. However, the wireless IC 32 instead of the battery control unit 40 may perform these functions. Note that the purpose of driving these circuits by the wireless IC 32 is to measure the parameters used for calculating the SOH, which is different from the original purpose as described above. For the voltage equalization circuit 80 and the module equalization circuit 81, it is exemplified that the battery monitoring unit 30 is provided. However, it is not limited thereto.

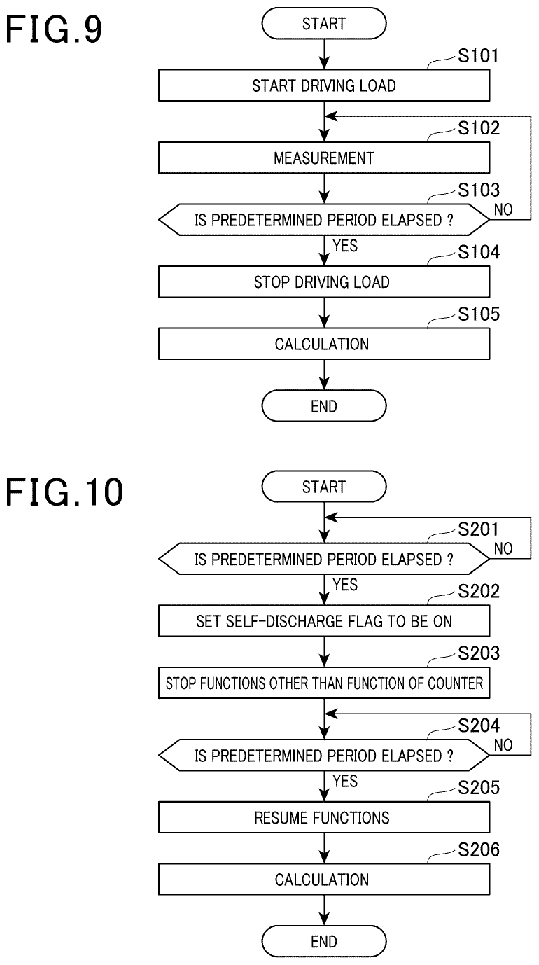

Next, with reference to the flowchart shown in FIG. 9, an operation example of a battery monitoring unit 30 (wireless IC 32 and monitoring IC 31) will be described. The processes shown in FIG. 9 are repeatedly executed at a predetermined interval.

At step S101, the wireless IC 32 transmits, at a predetermined timing after removing the battery module 21 from the battery pack 11, the voltage equalization command signal which has been performed by the battery control unit 40 before removing the battery module 21. Thus, the voltage equalization command circuit 80 is driven. Note that the predetermined timing is set in advance using an experience or a simulation, for example.

The process proceeds to step S102 at which the monitoring IC 31 measures at least either current flowing through the voltage equalization circuit 80 or voltage applied to the voltage equalization circuit 80. The process at step S102 is repeatedly executed until a predetermined period elapses (step S103). The predetermined period is measured by a counter 323. After the predetermined period elapses, the process proceeds to step S104 and the wireless IC 32 disables the voltage equalization circuit 80. This is because, since the purpose of driving the voltage equalization circuit 80 is to measure the current and the like, it is not necessary to drive the voltage equalization circuit 80 when the measurement of current is completed. Then, the process proceeds to step S105, the wireless IC 32 calculates the SOH of the battery cell 22 using the measured current and the like, and stores the calculation result into a storage unit itself (e.g. memory unit). The calculation result of the SOH may be stored as the calculation value itself or a histogram.

The timing at which the calculation result of the SOH stored in the storage unit is read, is not specifically limited, but the timing may be a timing at which the battery module 21 is mounted to the battery pack 11 as an example.

According to the first embodiment described in detail, the following effects and advantages can be obtained.

The battery pack 11 or the battery module 21 is configured to be exchangeable with respect to the motor 13. The battery pack 11 or the battery module 21 is provided with the battery cell 22, the voltage equalization circuit 80, the battery monitoring IC 31 and the wireless IC 32. The battery cell 22 is capable of supplying power to the motor 13 in a state where the battery pack 11 or the battery module 21 is connected to the motor 13. The voltage equalization circuit 80 is connected to the battery cell 22. The monitoring IC 31 measures at least either the current flowing through the voltage equalization circuit 80 or the voltage applied to the battery load. The wireless IC 32 is configured to operate with the battery cell 22 as a power source in a state where the battery pack 11 or the battery module 21 is removed from the motor 13. The wireless IC 32 causes the current to flow to the voltage equalization circuit 80 from the battery cell 22 at a predetermined timing and acquires a measurement result which is measured by the monitoring IC 31 at the predetermined timing. The motor 13 corresponds to an external load. The battery cell 22 corresponds to a battery member. The voltage equalization circuit 80 corresponds to a battery load. The monitoring IC 31 corresponds to a measurement unit. The wireless IC 32 corresponds to a control unit.

According to the present embodiment, the battery pack 11 or the battery module 21 causes the battery cell 22 to be discharged to measure the current at a predetermined timing. The measured current can be used for calculating the SOH for example. As described above, according to the conventional art, charging or a discharging cannot be performed after removing the battery pack or battery module. Hence, the SOH after removing battery pack or module cannot be detected. In contrast, according to the present embodiment, since the battery cells 22 are caused to be discharged to calculate the SOH, the SOH after removing the battery module can be detected.

According to the present embodiment, a case is described in which the SOH of the battery cells 22 that constitute the battery module 21 are calculated mainly in a state where the battery module 21 is removed from the battery pack 11. However, it is not limited thereto. As shown in FIG. 4, in a state where the battery pack 11 is removed from the vehicle 10, the SOH of the battery cells 22 that constitute the battery pack 11 may be calculated. Further, in recent years, various methods are developed including a method for mounting the battery cells directly to the battery pack without constituting the battery module, a method for mounting the battery modules directly to the vehicle body in which the housing part of the battery pack is integrated to the vehicle body, and a method for mounting the battery cells directly to the vehicle body.

Hence, according to the present embodiment, the SOH of the battery cell 22 may be calculated in a state where the battery cells 22 directly mounted to the vehicle 10 are removed from the vehicle 10. In this case, the battery monitoring unit 30 is attached to the battery cells 22. Moreover, the SOH of the battery cells 22 that constitute the battery module 21 may be calculated in a state where the battery module 21 directly mounted to the vehicle 10 is removed from the vehicle 10. That is, the battery unit includes a battery pack to which the battery monitoring unit 30 is mounted, a battery module to which the battery monitoring unit 30 is mounted or a battery cell to which the battery monitoring unit 30 is mounted.

Further, the wireless IC 32 may calculate and store the SOH of the battery cell 22 based on the measurement result measured by the monitoring IC 31 in a state where the battery pack 11 or the battery module 21 is removed from the motor 13. Thus, the SOH after removing the battery pack 11 or the battery module 21 can be detected.

Also, the wireless IC 32 notifies the battery control unit 40 of a measurement result measured by the monitoring IC 31 in accordance with the battery control unit 40 which communicates with the wireless IC 32 in a state where the battery pack 11 or the battery module 21 is connected to the motor 13. On the other hand, in a state where the battery pack 11 or the battery module 21 is disconnected from the motor 13, the wireless IC 32 performs a calculation of the SOH which is not performed in a state where the battery pack 11 or the battery module 21 is connected to the motor 13. For a calculation of SOH which is performed by the battery control unit 40 before removing the battery pack 11 or the battery module 21, the wireless IC 32 performs the calculation of the SOH in a state where the battery pack 11 or the battery module 21 is removed. Thus, the SOH can be calculated without adding new functions or apparatuses.

The wireless IC 32 determines whether the communication with the battery control unit 40 is cutoff. The wireless IC 32 determines that the battery pack 11 or the battery module 21 is removed from the motor 13, when determined that the communication with the battery control unit 40 is cutoff. In response to the determination, the wireless IC 32 causes the voltage equalization circuit 80 to flow current from the battery cell 22. Thus, the SOH can be calculated at an appropriate timing.

The wireless IC 32 determines that the communication with the battery control unit 40 is cutoff, when the activation command signal or the voltage equalization command signal of the battery cells 22 has not been received from the battery control unit 40 for a prescribed period, or when receiving a signal indicating that the communication with the external apparatus 70 is cutoff. Thus, the signal transmitted from the battery control unit 40 or the external apparatus 70 is utilized, whereby it can be appropriately determined whether the communication is cutoff.

The battery load includes a circuit utilized for equalizing the voltage (voltage equalization circuit 80, module equalization circuit 81) as described with reference to FIGS. 7 and 8. Also, the battery load may include a load utilized for adjusting the temperature state of the battery cell 22. The load utilized for adjusting the temperature state of the battery cell 22 is integrated into the battery pack 11, serving as a heater for heating the battery cell 22. Further, the battery load may include a load used for supplying a flow of current when measuring the impedance of the battery cell 22. Such an existing load is utilized, whereby the SOH can be calculated without adding new functions or apparatuses.

### Second Embodiment

Next, with reference to a flowchart shown in FIG. 10, a second embodiment will be described. According to the first embodiment, the voltage equalization circuit 80 is driven to discharge the battery cell 22, thereby calculating the SOH, in which the purpose is different from the original purpose. However, according to the second embodiment, a change in a self-discharge rate of the battery cell 22 is utilized to calculate the SOH.

At step S201 shown in FIG. 10, the wireless IC 32 maintains a waiting state until a prescribed period elapses, after the battery module 21 is removed from the battery pack 11. After elapse of the prescribed period (step S201: YES), the process proceeds to step S202, and the wireless IC 32 turns a flag related to the self-discharge to be ON. Note that the wireless IC 32 may turn the flag related to the self-discharge to be ON, based on a command transmitted from the external apparatus 70. Then, the process proceeds to step S203, and the wireless IC 32 stops functions other than that of the counter 323. The reason for stopping the functions other than that of the counter 323 is to prevent current other than current caused by the self-discharge from flowing through the circuit. Then, the process proceeds to step S204 and maintains a waiting state where the functions other than counter 322 are stopped for a prescribed period (i.e. causing the battery cells 22 to be self-discharged).

After elapsing a prescribed period (step S204: YES), the process proceeds to step S205 and the wireless IC 32 resumes the functions which are stopped. Then, the process proceeds to step S206 and the wireless IC 32 calculates a change in the self-discharge rate of the battery cell 22. An example of calculating the change in the self-discharge rate includes a method of calculating the change in the self-discharge based on a state of charge (SOC) of the battery cell 22 at a time when the counting of prescribed period is started, and a change rate of the state of charge (SOC) of the battery cell 22 at a time when the counting of prescribed period is completed. The state of charge can be calculated using voltage, current, temperature and the like of the battery cell 22. The wireless IC 32 calculates the SOH based on the change in the self-discharge rate of the battery cell 22.

According to the second embodiment, the following effects and advantages can be obtained.

The battery pack 11 or the battery module 21 is configured to operate with the battery cell 22 as a power source in a state where the battery pack 11 or the battery module 21 is removed from the motor 13, and includes the wireless IC 32 that calculates a change in the self-discharge rate of the battery cell 22. The calculated change in the self-discharge rate can be used for a calculation of the SOH for example. Since the change in the self-discharge rate can be calculated without adding new functions or apparatuses, cost can be reduced for calculating the SOH.

The wireless IC 32 disables functions other than that of the counter 323 that measures a time required for the self-discharge. Thus, current other than a current due to the self-discharge can be prevented from flowing through the circuit, whereby an accuracy for calculating the change in the self-discharge rate can be improved. The wireless IC 32 calculates the change in the self-discharge rate based on a change rate between a state of charge of the battery cell 22 at a time when starting to count the prescribed period and a state of charge of the battery cell 22 at a time when the prescribed period elapses. Then, the wireless IC 32 calculates and stores the SOH of the battery cell 22 based on the calculated change in the self-discharge rate.

### Other Embodiments

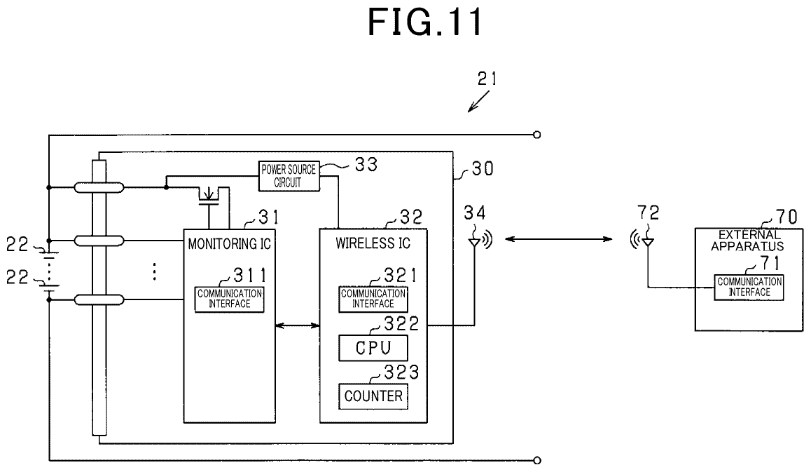

According to the above-described embodiments, it is described that the wireless IC 32 stores the calculation result of the SOH into the storage unit itself. However, it is not limited thereto. As shown in FIG. 11, the wireless IC 32 may transmit the calculation result of the SOH to the external apparatus 70 (e.g. cloud server) using a wireless communication. In the case where the wireless communication is utilized, a physical interface such as a connector is not required. Moreover, it is described that the wireless IC 32 in the above-described embodiment calculates the SOH using the measured current or the like. However, it is not limited thereto. As shown in FIG. 11, the wireless IC 32 may transmit the measured current and the like to the external apparatus 70 and the external apparatus 70 may calculate the SOH. In this case, the wireless IC 32 is only required to have a function of storing and transmitting the measured current and the like. Moreover, both of the wireless IC 32 and the external apparatus 70 may calculate the SOH. In this case, both calculation results are compared to verify the validity of the calculation results. In the case where the calculation results are different, the difference may be used for the next calculation as a correction factor.

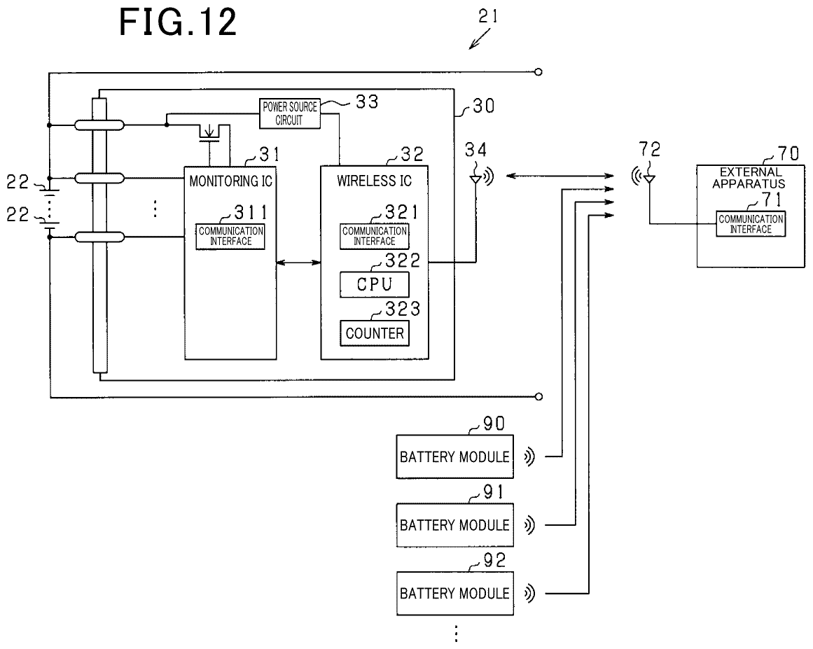

As shown in FIG. 12, in the case where battery modules 90 to 92 of which the specification is different from that of the battery module 21 are present other than the battery module 21 according to the present embodiment, SOHs calculated by these battery modules may be integrally transmitted to the external apparatus 70. Such a transmission of SOH data can be accomplished with the same communication frequency, for example. Thus, the battery modules of which the specifications are different can be integrally managed.

When a storage state of the battery cell 22 is less than or equal to a prescribed value, the wireless IC 32 may stop causing the current to flow to the battery load from the battery cell 22. Thus, the battery cell 22 can be prevented from being over-discharged.

A frequency of how often the monitoring IC 31 operates may be set, after removing the battery pack 11 from the vehicle 10, to be lower than that of a case before removing the battery pack 11 is removed from the vehicle 10. The monitoring IC 31 may include one failure diagnosis function. The number of failure diagnosis operations may be reduced after removing the battery pack from the vehicle 10 compared to a case before removing the battery pack 11 from the vehicle 10. This is because, demand for the failure diagnosis operation is lower after the battery pack 11 is removed from the vehicle 10.

The wireless IC 32 may utilize, as a signal for driving the voltage equalization circuit 80 or the module equalization circuit 81, a dedicated signal which is not a signal used for the battery control unit 40. That is, the signal is not limited as long as the voltage equalization circuit 80 and the like can be driven.

The control unit and method thereof disclosed in the present disclosure may be accomplished by a dedicated computer constituted of a processor and a memory programmed to execute one or more functions embodied by computer programs. Alternatively, the control unit and method thereof disclosed in the present disclosure may be accomplished by a dedicated computer provided by a processor configured of one or more dedicated hardware logic circuits. Further, the control unit and method thereof disclosed in the present disclosure may be accomplished by one or more dedicated computers where a processor and a memory programmed to execute one or more functions, and a processor configured of one or more hardware logic circuits are combined. Furthermore, the computer programs may be stored, as instruction codes executed by the computer, into a computer readable non-transitory tangible recording media.

Hereinafter, significant configurations obtained from the above-described embodiments will be described.

### Configuration 1

A battery unit (11, 21, 22) configured to be exchangeable with respect to an external load (13), the battery unit comprising:
a battery member (22) capable of supplying power to the external load in a state where the battery unit is connected to the external load;
a battery load (80) connected to the battery member;
a measurement unit (31) that measures at least either a current flowing through the battery load or a voltage applied to the battery load; and
a control unit (32) configured to operate with the battery member as a power source in a state where the battery unit is removed from the external load, cause a current to flow to the battery load from the battery member at a predetermined timing and acquire a measurement result measured by the measurement unit at a time when the current is caused to flow.

### Configuration 2

The battery unit according to configuration 1, wherein
the control unit calculates a battery state of the battery member based on the measurement result in a state where the battery unit is removed from the external load and stores the calculated battery state.

### Configuration 3

The battery unit according to either configuration 1 or 2, wherein
the control unit notifies, in accordance with a command transmitted from a battery control unit that communicates with the control unit, the battery control unit of the measurement result, in a state where the battery unit is connected to the external load; and
the control unit performs, in a state where the battery unit is removed from the external load, a calculation of the battery state which has not been performed in a state where the battery unit is connected to the external load.

### Configuration 4

The battery unit according to configuration 3 further comprising a determination unit that determines whether a communication between the control unit and the battery control unit is cutoff, wherein
the control unit determines, when the determination unit determines that the communication between the control unit and the battery control unit is cutoff, that the battery unit is removed from the external load, and causes a current to flow to the battery load from the battery member in response to the determination of the control unit, thereby causing the measurement unit to perform the measurement.

### Configuration 5

The battery unit according to configuration 4, wherein
the determination unit determines that the communication between the control unit and the battery control unit is cutoff, when an activation command signal or a voltage equalization command signal has not been received for a prescribed period, or when receiving a signal indicating that a communication with an external apparatus is cutoff.

### Configuration 6

The battery unit according to any one of configurations 1 to 5, wherein
the battery load is configured as any one of a load utilized for equalizing voltages of the battery member, a load utilized for adjusting a temperature state of the battery member, and a load utilized for causing a current to flow when measuring an impedance.

### Configuration 7

The battery unit according to configuration 5, wherein
the control unit is configured to be capable of being communicating with the external apparatus.

### Configuration 8

The battery unit according to any one of configurations 1 to 7, wherein
the control unit stops causing a current to flow to the battery load from the battery member when a storage state of the battery member is less than or equal to a prescribed value.

### Configuration 9

A battery unit (11, 21, 22) configured to be exchangeable with respect to an external load (13), the battery unit comprising:
a battery member (22) capable of supplying power to the external load in a state where the battery unit is connected to the external load;
a control unit (32) configured to operate with the battery member as a power source in a state where the battery unit is removed from the external load, and calculate a change in a self-discharge rate of the battery member.

### Configuration 10

The battery unit according to configuration 9, wherein
the control unit stops functions except a function of a counter for measuring a time for a self-discharge for a prescribed period, calculates a change in the self-discharge rate based on a change rate between a state of charge of the battery member at a time when starting to count the prescribed period and a state of charge of the battery member at a time when completing to count the prescribed period, calculates a battery state of the battery member based on the calculated self-discharge rate and stores the calculated battery state.

### Configuration 11

A battery monitoring apparatus mounted to a battery unit (11, 21, 22) configured to be exchangeable with respect to an external load (13), the battery monitoring apparatus comprising:
a measurement unit (31) that measures at least either a current flowing through a battery load (80) connected to a battery member (22) of the battery unit or a voltage applied to the battery load; and
a control unit (32) configured to operate with the battery member as a power source in a state where the battery unit is removed from the external load, cause a current to flow to the battery load from the battery member at a predetermined timing and acquire a measurement result measured by the measurement unit at a time when the current is caused to flow.

The present disclosure has been described in accordance with the embodiments. However, the present disclosure is not limited to the embodiments and structure thereof. The present disclosure includes various modification examples and modifications within the equivalent configurations. Further, various combinations and modes and other combinations and modes including one element or more or less elements of those various combinations are within the range and technical scope of the present disclosure.

### Conclusion

The present disclosure provides a battery unit and battery monitoring apparatus capable of detecting a battery state after removing an exchangeable battery unit.

Specifically, the present disclosure provides a battery unit configured to be exchangeable with respect to an external load, including a battery member capable of supplying power to the external load in a state where the battery unit is connected to the external load; a battery load connected to the battery member, a measurement unit that measures at least either a current flowing through the battery load or a voltage applied to the battery load; and a control unit configured to operate with the battery member as a power source in a state where the battery unit is removed from the external load, cause a current to flow to the battery load from the battery member at a predetermined timing and acquire a measurement result measured by the measurement unit at a time when the current is caused to flow.

The battery unit discharges the battery member at a predetermined timing to measure the current or the like. The measured current can be used for calculating the battery state for example. As described above, according to a conventional art, since charging/discharging cannot be performed after removing the battery module, the battery state of the battery module cannot be detected after removing the battery module. In contrast, according to the present disclosure, the battery member is caused to be discharged to acquire the measurement result. Hence, the battery state after removing the battery unit can be detected.

The present disclosure provides a battery unit configured to be exchangeable with respect to an external load, including a battery member capable of supplying power to the external load in a state where the battery unit is connected to the external load; and a control unit configured to operate with the battery member as a power source in a state where the battery unit is removed from the external load, and the control unit calculating a change in a self-discharge rate of the battery member.

The calculated change in the self-discharge rate can be used for calculating the battery state for example. Accordingly, since the change in the self-discharge rate can be calculated without adding new functions and apparatuses, a cost reduction can be achieved in an apparatus calculating the battery state.

The present disclosure provides a battery monitoring apparatus mounted to a battery unit configured to be exchangeable with respect to an external load, including a measurement unit that measures at least either a current flowing through a battery load connected to a battery member of the battery unit or a voltage applied to the battery load; and a control unit configured to
operate with the battery member as a power source in a state where the battery unit is removed from the external load,
cause a current to flow to the battery load from the battery member at a predetermined timing and
acquire a measurement result measured by the measurement unit at a time when the current is caused to flow.

The battery monitoring apparatus discharges the battery member at a predetermined timing to measure the current and the like. The measured current and the like can be utilized for calculating the battery state for example. As described above, according to a conventional art, since charging/discharging cannot be performed after removing the battery module, the battery state after removing cannot be detected. In contrast, according to the present disclosure, since the measurement result is acquired by discharging the battery member, the battery state after removing the battery unit can be detected.

What is claimed is:

1. A battery unit configured to be exchangeable with respect to an external load, the battery unit comprising:
a battery member capable of supplying power to the external load in a state where the battery unit is connected to the external load;
a battery load connected to the battery member,
a measurement unit that measures at least either a current flowing through the battery load or a voltage applied to the battery load; and
a control unit configured to operate with the battery member as a power source in a state where the battery unit is removed from the external load, cause a current to flow to the battery load from the battery member at a predetermined timing and acquire a measurement result measured by the measurement unit at a time when the current is caused to flow.

2. The battery unit according to claim 1, wherein
the control unit calculates a battery state of the battery member based on the measurement result in a state where the battery unit is removed from the external load and stores the calculated battery state.

3. The battery unit according to claim 2, wherein
the control unit notifies, in accordance with a command transmitted from a battery control unit that communicates with the control unit, the battery control unit of the measurement result, in a state where the battery unit is connected to the external load; and
the control unit performs, in a state where the battery unit is removed from the external load, a calculation of the battery state which has not been performed in a state where the battery unit is connected to the external load.

4. The battery unit according to claim 3 further comprising a determination unit that determines whether a communication between the control unit and the battery control unit is cutoff, wherein
the control unit determines, when the determination unit determines that the communication between the control unit and the battery control unit is cutoff, that the battery unit is removed from the external load, and causes a current to flow to the battery load from the battery member in response to the determination of the control unit, thereby causing the measurement unit to perform the measurement.

5. The battery unit according to claim 4, wherein
the determination unit determines that the communication between the control unit and the battery control unit is cutoff, when an activation command signal or a voltage equalization command signal has not been received for a prescribed period, or when receiving a signal indicating that a communication with an external apparatus is cutoff.

6. The battery unit according to claim 1, wherein
the battery load is configured as any one of a load utilized for equalizing voltages of the battery member, a load utilized for adjusting a temperature state of the battery member, and a load utilized for causing a current to flow when measuring an impedance.

7. The battery unit according to claim 5, wherein
the control unit is configured to be capable of communicating with the external apparatus.

8. The battery unit according to claim 1, wherein
the control unit stops causing a current to flow to the battery load from the battery member when a storage state of the battery member is less than or equal to a prescribed value.

9. A battery unit configured to be exchangeable with respect to an external load, the battery unit comprising:
a battery member capable of supplying power to the external load in a state where the battery unit is connected to the external load;
a control unit configured to operate with the battery member as a power source in a state where the battery unit is removed from the external load, and calculate a change in a self-discharge rate of the battery member.

10. The battery unit according to claim 9, wherein
the control unit stops functions except a function of a counter for measuring a time for a self-discharge for a prescribed period in a state where the battery unit is removed from the external load,
calculates a change in the self-discharge rate based on a change rate between a state of charge of the battery member at a time when starting to count the prescribed period and a state of charge of the battery member at a time when completing to count the prescribed period, calculates a battery state of the battery member based on the calculated self-discharge rate and stores the calculated battery state.

11. A battery monitoring apparatus mounted to a battery unit configured to be exchangeable with respect to an external load, the battery monitoring apparatus comprising:
a measurement unit that measures at least either a current flowing through a battery load connected to a battery member of the battery unit or a voltage applied to the battery load; and
a control unit configured to operate with the battery member as a power source in a state where the battery unit is removed from the external load, cause a current to flow to the battery load from the battery member at a predetermined timing and acquire a measurement result measured by the measurement unit at a time when the current is caused to flow.
